(19) United States
(12) Patent Application Publication
(10) Pub. No.: US 2011/0230045 A1
(43) Pub. Date: Sep. 22, 2011

(54) METHOD OF MANUFACTURNING SEMICONDUCTOR DEVICE

(76) Inventor: Byoung Sub NAM, Cheongju-si (KR)

(21) Appl. No.: 12/981,646

(22) Filed: Dec. 30, 2010

(30) Foreign Application Priority Data
Mar. 17, 2010 (KR) 10-2010-0023853

(51) Int. Cl. H01L 21/768

(52) U.S. Cl. 438/618; 257/E21.575

(57) ABSTRACT

A method of manufacturing a semiconductor device capable of improving a margin of a fabrication process of the semiconductor device, suppressing defect occurrence, and reducing a minimum design rule of a fine pattern is provided. The method of manufacturing a semiconductor device includes forming an input/output (I/O) pad and a metal interconnection, each of the I/O pad and the interconnection including a plurality of line patterns, the plurality of line patterns having the same line widths as each other and being separated by the same distance.

### CROSS-REFERENCES TO RELATED APPLICATION

Priority to Korean patent application number 10-2010-0023853, filed on Mar. 17, 2010, which is incorporated by reference in its entirety, is claimed.

### BACKGROUND OF THE INVENTION

The inventive concept relates to a method of manufacturing a semiconductor device, and more particularly, to a method of manufacturing a semiconductor device capable of reducing a minimum design rule of a fine pattern formable through one exposure process.

Semiconductor devices are devices capable of operating according to specific purposes. Semiconductor devices are formed through a process of injecting impurities in a predetermined region of a silicon wafer, and depositing one or more layers of various materials. Semiconductor devices include semiconductor memory devices. The semiconductor memory devices include transistors, capacitors, resistors, fuses or the like to perform specific purposes therein.

Recently, attempts have been made to improve semiconductor devices to be highly integrated and to be reduced in power consumption. As the semiconductor devices become more highly integrated, sizes of elements included in the semiconductor devices are reduced. More specifically, a cross-sectional area occupied by transistors and capacitors is reduced as widths and cross-sectional areas of interconnections for connecting elements are reduced.

FIGS. 1A to 1C are plan views illustrating various types of patterns formed in general semiconductor devices.

FIG. 1A illustrates a plurality of line patterns 102 included in a semiconductor device. As shown, the line patterns 102 are parallel lines of the same layer and are separated from one another by a space. FIG. 1A also illustrates that the semiconductor device may include connection patterns 104 having a lateral direction and cramp patterns 106 having a ‘ [symbol] ’ shape which connect certain line patterns 102.

Referring to FIG. 1B, a semiconductor device may include a plurality of line patterns 112, having substantially the same line width and being separated by substantially the same distance. FIG. 1B also shows that the semiconductor device may include misaligned line patterns 114 which have different line widths and/or are separated by different distances than the line patterns 112.

Referring to FIG. 1C, a semiconductor device may include a plurality of line patterns 122, having substantially the same line width and being separated by substantially the same distance. FIG. 1C also shows that the semiconductor device may include input/output (I/O) pad patterns 124 which have different line widths and/or are separated by different distances than the line patterns 122.

Referring to FIGS. 1A to 1C, because the cramp patterns 106, the misaligned line patterns 114, and the I/O pad patterns 124 may be formed with different line widths and separated by different distances, it may be difficult to form patterns by an exposure process. When line widths and distances of patterns formed on a semiconductor substrate are different from each other, process margins according to patterns are also changed. When a plurality of patterns formed by one exposure process have different process margins from each other, portions of the patterns are normally formed and other portions of the patterns are more likely to be abnormally formed. In particular, when density of fine patterns in a cell area, including a plurality of unit cells, and a core area of a semiconductor memory device is high, even a minute difference in a process margin may cause defects.

When densities of patterns in each area of the semiconductor device are different, it may be difficult to set a target of critical dimension (CD) of a mask defining the patterns and a target of CD of optical proximity correction (OPC). In addition, chemical flare phenomena due to chemical uniformity between a region in which dense patterns are transferred and a region in which sparse patterns are transferred may cause defects in the semiconductor device. To address the aforementioned concerns regarding patterns having different line widths and distances, a number of exposure processes are used, and thus, productivity is reduced as well.

### SUMMARY

According to one aspect of an exemplary embodiment, a method of manufacturing a semiconductor device includes forming an input/output (I/O) pad and a metal interconnection, each of the I/O pad and the interconnection including a plurality of line patterns, the plurality of line patterns having the same line widths as each other and being separated by the same distance from each other.

The I/O pad and the metal interconnection may be disposed in a core area of the semiconductor device.

The forming of the I/O pad and the metal interconnection may include forming connection patterns to connect between the plurality of line patterns in a direction crossed with the line patterns.

One of the line patterns connected to each connection pattern may include a dummy region.

The dummy region may be a portion of the one line pattern that extends to over 50 nm from the connection pattern.

The ratio between the line width and the distance between adjacent line patterns may be 1:1.

The line width of each line pattern formed by a single patterning process may be 38 nm to 44 nm.

These and other features, aspects, and embodiments are described below in the section entitled “DESCRIPTION OF EXEMPLARY EMBODIMENTS”.

### BRIEF DESCRIPTION OF THE DRAWINGS

The above and other aspects, features, and advantages of the subject matter of the present disclosure will be more clearly understood from the following detailed description and the accompanying drawings, in which:

FIGS. 1A to 1C are plan views illustrating various types of patterns formed in a general semiconductor device; and

FIGS. 2A to 2C are plan views illustrating patterns formed by a method of manufacturing a semiconductor device according to exemplary embodiments of the inventive concept.

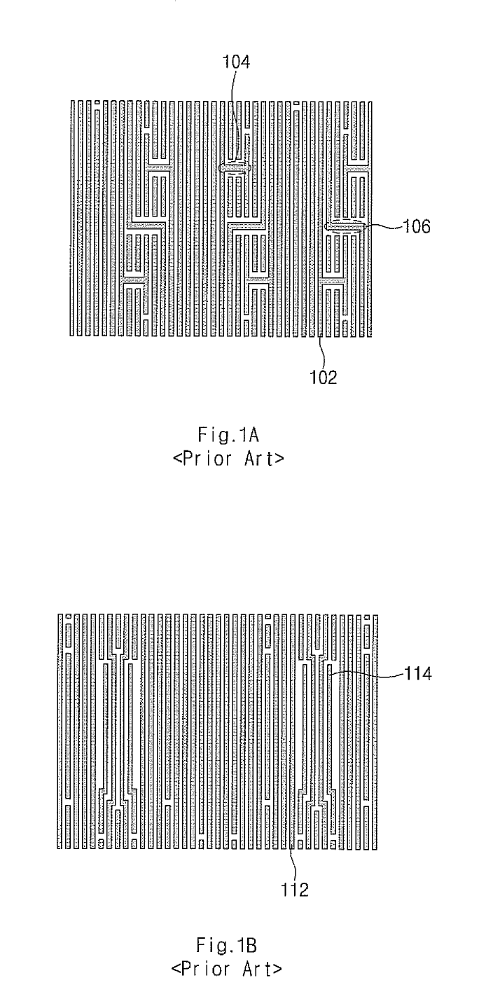

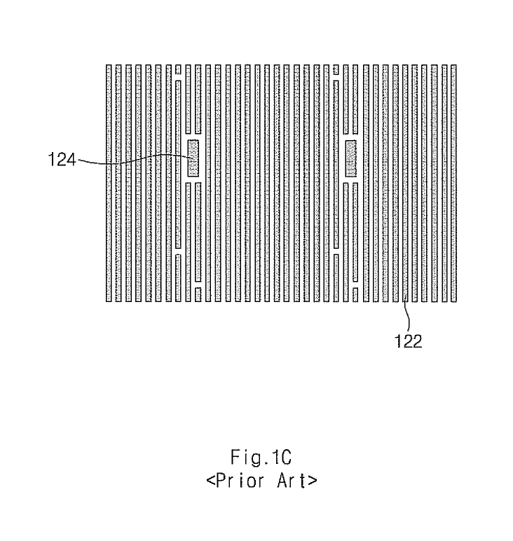

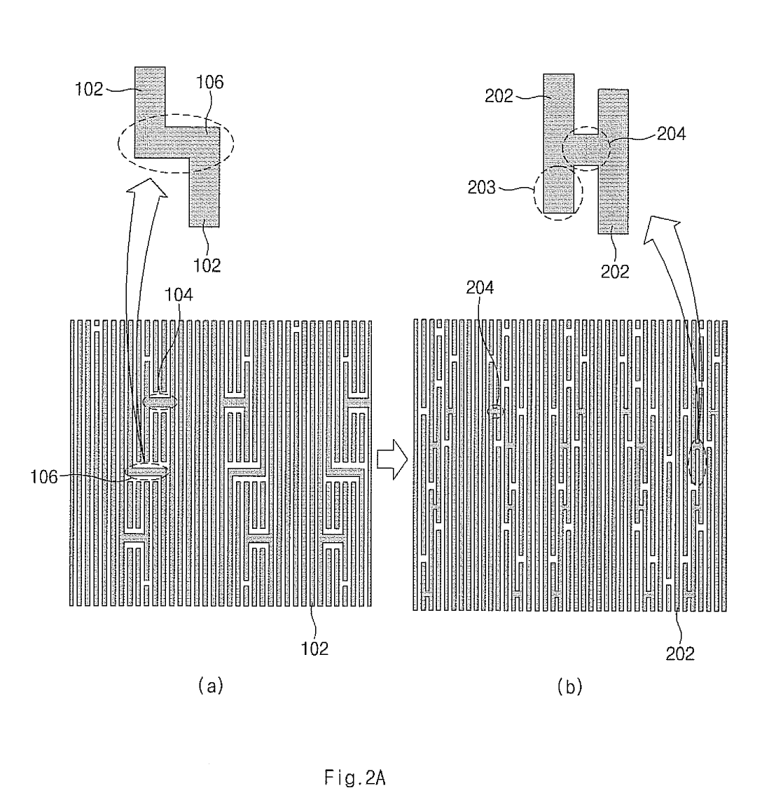

### DESCRIPTION OF EXEMPLARY EMBODIMENTS

Exemplary embodiments are described herein with reference to illustrations of exemplary embodiments (and intermediate structures). As such, variations from the shapes of the illustrations as a result of, for example, manufacturing techniques and/or tolerances, are to be expected. Thus, exemplary embodiments should not be construed as limited to the particular shapes of regions illustrated herein. In the drawings, lengths and sizes of layers and regions may be exaggerated for clarity. Like reference numerals in the drawings denote like elements. It is also understood that when a layer is referred to as being “on” another layer or substrate, it can be directly on the other layer or substrate, or intervening layers may also be present.

The inventive concept modifies a general technology used to fabricate a semiconductor memory device in which various kinds of elements, included in a core area, have patterns with different line widths and distances from each other. The modification changes a layout of the semiconductor memory device so that a plurality of elements in the semiconductor memory device are formed from line patterns all having the same line widths and distances. That is, the inventive concept redesigns the patterns generally having different line widths and distances, such as cramp patterns, misaligned line patterns, input/output (I/O) patterns, and the like, to form line patterns having the same line widths and distances.

Hereinafter, exemplary embodiments of the invention concept will be described in further detail with reference to the accompanying drawings.

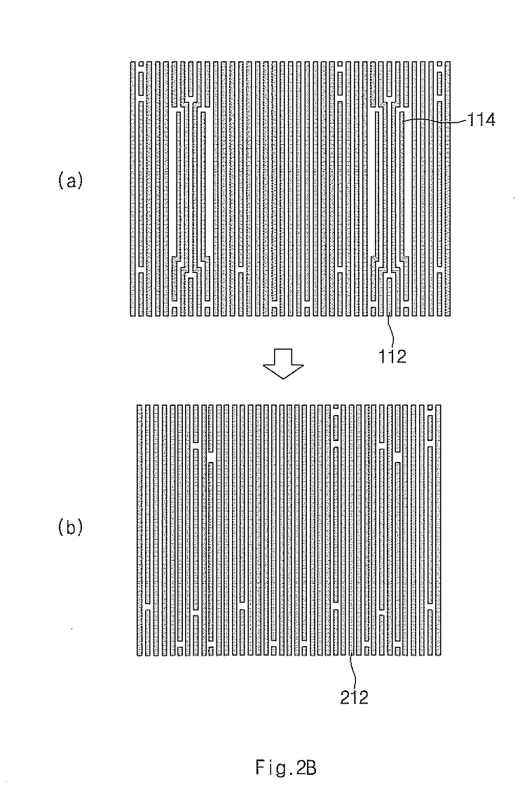

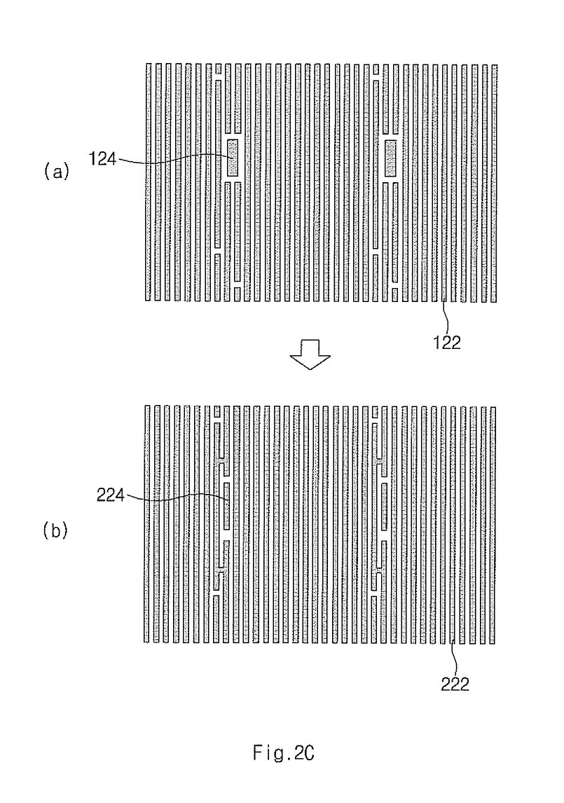

FIGS. 2A to 2C are plan views illustrating patterns formed by a method of manufacturing a semiconductor device according to exemplary embodiments of the inventive concept.

Referring to FIG. 2A(a), a plurality of line patterns 102, connection patterns 104, and cramp patterns 106 are included in a semiconductor device of related art. If elements of the semiconductor device of the related art are designed as the line patterns 202 having the same line widths and distances, the semiconductor device of the related art are modified into a semiconductor device of FIG. 2A(b). Referring to FIG. 2A(b), elements of a semiconductor device of the inventive concept are formed from the plurality of line patterns 202 and a plurality of connection patterns 204. Herein, the plurality of line patterns 202 may be designed so that a ratio of the line width and the distance between each line pattern 202 becomes 1:1.

All the cramp patterns 106 formed in a ‘ [symbol] ’ shape of the related art may be modified into a combination of the line patterns 202 and the connection patterns 204. In particular, a dummy region 203 is formed to be extended from a region in which the connection pattern 204 is connected to the line pattern 202, thereby increasing a process margin. At this time, the dummy region 203 may be formed to have a length of about 50 nm or more.

Referring to FIG. 2B(a), misaligned line patterns 114 are included between a plurality of line patterns 112 in a semiconductor device of related art. According to the inventive concept as shown in FIG. 2B(b), the misaligned line patterns 114 of the related art are redesigned to form line patterns 212 having the same line widths and distances between each other.

When metal interconnections which are formed in the misaligned line patterns 114 are modified into the line patterns 212 having the same line widths and distances, an electrical connection between the metal interconnection and a word line or an active region formed below the metal interconnection must be considered. In the related art, the misaligned line patterns 114 forming the metal interconnections are determined according to a layout of the word line or the active region. However, according to the inventive concept, positions of gate lines or active regions formed below the line patterns 212 may be adjusted based on the line patterns 212 for forming metal interconnections, or to alleviate a design rule so that a line width or an area of the line pattern 212 can be increased as compared with the related art. It may be easier to adjust positions of the gate lines or the active regions in a core area, as compared with adjusting the line widths or distances of the plurality of metal interconnections in the cell area of the semiconductor memory device because the core area may have more available space.

Referring to FIG. 2C(a), I/O pad patterns 124 are included between a plurality of line patterns 122 in a semiconductor device of related art. The inventive concept may reduce sizes of the I/O pad patterns 124 of the related art to have the same line widths as other line patterns 222 and adjust distances of the I/O pad patterns 124 of the related art to have the same distances between adjacent line patterns 222 as shown in FIG. 2C(b). That is, in accordance with the inventive concept, the I/O pad patterns 224 have the same line-width and are separated by the same distance as the line patterns 222.

Sense amplifiers connected to a plurality of unit cells and various switching circuits are disposed in the core area of the semiconductor memory device, and therefore, the core area may be very complicated. Thus, a plurality of elements such as interconnections, pads, contacts, and the like included in the core area are formed as patterns having different line widths and distances in the related art. However, patterns having different line widths and distances such as cramp patterns, misaligned line patterns, I/O pad patterns, and the like are designed using line patterns having the same line widths and distances in semiconductor devices in accordance with the inventive concept. According to exemplary embodiments, elements such as metal interconnections, pads, and the like formed above a capacitor can be embodied as line patterns having the same line widths and aligned with the same distances in vertical and horizontal directions.

Thus, it is possible to reduce a minimum design rule to a range of 44 nm to 38 nm using a single patterning process and improve a depth of field (DOF) of above 30 nm in an exposure process of 4×nm grade (40 nm to 49 nm). In addition, patterns of elements of the semiconductor device are simplified to form line patterns having the same line widths and distances so that the method of manufacturing the semiconductor device may be applied to a double patterning process using a spacer.

The above embodiments of the present invention are illustrative and not limitative. Various alternatives and equivalents are possible. The invention is not limited by the type of deposition, etching, polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method of manufacturing a semiconductor device, comprising forming an input/output (I/O) pad and a metal interconnection, each of the I/O pad and the interconnection including a plurality of line patterns, the plurality of line patterns having the same line widths as each other and being separated by the same distance from each other.

2. The method of claim 1, wherein the I/O pad and the metal interconnection are disposed in a core area of the semiconductor device.

3. The method of claim 1, wherein the forming of the I/O pad and the metal interconnection includes forming connection patterns to connect between the plurality of line patterns in a direction crossed with the line patterns.

4. The method of claim 3, wherein one of the line patterns connected to each connection pattern includes a dummy region.

5. The method of claim 4, wherein the dummy region is a portion of the one line pattern that extends to over 50 nm from the connection pattern.

6. The method of claim 1, wherein a ratio between the line width and the distance between adjacent line patterns is 1:1.

7. The method of claim 1, wherein the line width of each line pattern formed by a single patterning process is 38 nm to 44 nm.
